(19) United States
(12) Patent Application Publication
(10) Pub. No.: US 2010/0193232 A1
(43) Pub. Date: Aug. 5, 2010

(54) PRINTED CIRCUIT BOARD AND METHOD OF MANUFACTURING THE SAME

(76) Inventors: Myung Sam Kang, Gyunggi-do (KR); Ok Tae Kim, Gyunggi-do (KR); Gil Yong Shin, Jeollabuk-do (KR); Kil Yong Yun, Gyunggi-do (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/424,511

(22) Filed: Apr. 15, 2009

(30) Foreign Application Priority Data
Feb. 3, 2009 (KR) 10-2009-0008482

(51) Int. Cl. H05K 1/11; H05K 3/10

(52) U.S. Cl. 174/261; 29/846

(57) ABSTRACT

Disclosed herein are a printed circuit board and a process of manufacturing the printed circuit board. The printed circuit board includes an insulating layer, and circuit layers disposed at both sides of the insulating layer, each of the circuit layers including a land part and a pattern part. The land parts formed on both sides of the insulating layer are coupled to each other using electrical resistance welding. There is no need for a separate interlayer connection structure such as vias or bumps and a process of forming the interlayer connection structure, thus simplifying the printed circuit board and the process.

### CROSS REFERENCE TO RELATED APPLICATION

This application claims the benefit of Korean Patent Application No. 10-2009-0008482, filed Feb. 3, 2009, entitled “A printed circuit board and a fabricating method the same”, which is hereby incorporated by reference in its entirety into this application.

### BACKGROUND OF THE INVENTION

1. Field of the Invention

The present invention relates to a printed circuit board and a method of manufacturing the same, and more particularly to a printed circuit board and a method of manufacturing the same, in which constituent layers are connected to each other through electrical resistance welding.

2. Description of the Related Art

Typically, a printed circuit board is manufactured in a manner such that a copper wire is patterned on one or both sides of a board that is made of one of various thermosetting synthetic resins, and ICs or electrical components are disposed on the board and electrically connected to each other, and the resulting board including the electrical components are coated with an insulating material.

In the manufacture of a printed circuit board, it will be understood that the most essential and critical process is to form a circuit pattern on an insulating layer. FIGS. 1 to 6 are cross-sectional views sequentially showing a conventional process of manufacturing a printed circuit board. The conventional process of manufacturing a printed circuit board will now be described with reference to the drawings.

As shown in FIG. 1, a double-sided copper clad laminate, which is composed of an insulating layer 12 and thin copper layers 14 formed on both sides of the insulating layer 12, is first prepared.

As shown in FIG. 2, a via-hole 16 is formed in the insulating layer 12 for interlayer connection. At this point, the via-hole 16 may be formed in a manner such that the copper layers 14 and the insulating layer 12 are machined at a single time using a CNC drill, a CO₂ laser drill or a YAG laser drill, or may be formed in a manner such that the copper layers 14 formed on the both sides of the insulating layer 12 are etched to form a window and then only the insulating layer 12 is drilled through the window.

As shown in FIG. 3, in order to electrically connect the layers to each other and to form a circuit layer on a surface of the insulating layer 12, an electroless plating layer 18 is formed on an inner wall of the via-hole 16 as well as the insulating layer 12. In this regard, the electroless plating layer 18 may be formed through a typical catalyst precipitation process using a catalyst which comprises a cleanet step, a soft etching step, a pre-catalyst step, a catalyst treatment step, an accelerator step, an electroless copper plating step and an oxidation step. In this specification, a detailed description of the catalyst precipitation process which is well known in the art is omitted for brevity.

As shown in FIG. 4, in order to form a wiring pattern, an electrolytic plating layer 20 is formed on the electroless plating layer 18 including the inner wall of the via-hole 16 through an electrolytic plating process.

As shown in FIG. 5, a dry film 22 is applied onto the electrolytic plating layer 20, and is then patterned through exposure and development processes to form openings 24 through which a pattern region is exposed.

As shown in FIG. 6, the electroless plating layer 18 and the electrolytic plating layer 20, which are exposed through the openings 24, are removed using an etching process, thus forming a pattern part 26. Subsequently, the dry film 22 is removed to provide the completed printed circuit board 30.

However, because the conventional process of manufacturing the printed circuit board 30 requires a series of processes such as formation of a via-hole 16 for interlayer connection and formation of electroless and electrolytic plating layers 18 and 20, the manufacturing process is complicated and production costs and a manufacturing time are increased.

Specifically, as a number of via-hole 16 are increase, the processes such as formation of a via-hole, and formation of electroless and electrolytic plating layers are more required, thus manufacturing process is more complicated and production costs and a manufacturing time are more increased.

### SUMMARY OF THE INVENTION

Accordingly, the present invention has been made keeping in mind the above problems occurring in the related art, and the present invention provides a printed circuit board which does not require provision of interlayer connection structures such as vias or bumps, and a method of manufacturing the same.

The present invention provides a printed circuit board which is manufactured by simple process using welding for interlayer connection, and a method of manufacturing the same.

In one aspect, the present invention provides a printed circuit board including: an insulating layer; and circuit layers disposed at both sides of the insulating layer, each of the circuit layers including a land part and a pattern part, wherein the land parts formed on both sides of the insulating layer are coupled to each other using electrical resistance welding.

The circuit layers may be embedded in the insulating layer.

The circuit layers may be disposed on the insulating layer.

A region of the printed circuit board at which the land parts are disposed may have a thickness less than that of a region of the printed circuit board at which the pattern parts are disposed.

In another aspect, the present invention provides a method of manufacturing a printed circuit board, including: (A) forming circuit layers on carrier members, respectively, each of the circuit layers including a land part and a pattern part; (B) disposing the carrier members on both sides of an insulating layer having a cavity at an interlayer connection region such that the circuit layers of the carrier members face each other; (C) pressing the carrier members so as to embed the circuit layers in the insulating layer; (D) pressing the carrier members using welding rods placed thereon such that the land parts disposed at both sides of the cavity come into contact with each other, and coupling the land parts to each other by executing electrical resistance welding via the welding rods; and (E) shaping the insulating layer at a high temperature under high pressure so as to fill a space between the circuit layers and the insulating layer with the insulating layer, and removing the carrier members.

The (A) disposition of the carrier members may include: (A1) disposing the carrier members on both sides of an adhesive layer, each of the carrier members including a metal base layer, a metal barrier layer and a seed layer; (A2) applying photosensitive resists on the seed layers, and patterning the photosensitive resists to form openings through which regions for formation of circuit layer are exposed; (A3) executing a plating process in the openings to form the circuit layers each including the land part and the pattern part, and removing the photosensitive resists; and (A4) separating the carrier members disposed on both sides of the adhesive layer from each other.

The adhesive layer may lose adhesive force when subjected to heat treatment.

In the (B) disposition of the carrier members, the carrier members may be disposed such that the land parts face each other with the cavity disposed therebetween.

In the (B) disposition of the carrier members, the cavity of the insulating layer may have a width greater than that of the land part.

In the (D) pressing of the carrier members, the welding rods may be placed on regions of the carrier members at which the land parts are positioned, the carrier members may be pressed to bring the land parts into contact with each other by the welding rods, and electrical current may be applied to the welding rods to weld the land parts to each other.

A region of the printed circuit board at which the land parts are disposed may have a thickness less than that of a region of the printed circuit board at which the pattern parts are disposed.

In still another aspect, the present invention provides a method of manufacturing a printed circuit board, including: (A) adhering metal layers to both sides of an insulating layer having a cavity at an interlayer connection region; (B) pressing the metal layers positioned at both sides of the cavity to bring the metal layers into contact with each other using welding rods placed on the metal layers, and coupling the metal layers to each other by electrical resistance welding; (C) shaping the insulating layer at a high temperature under high pressure so as to fill a space between the metal layers and the insulating layer with the insulating layer; and (D) patterning the metal layers to form circuit layers each including a land part and a pattern part.

In the (B) pressing of the metal layers, the welding rods may be placed on a region of the carrier members which are positioned at both sides of the cavity, the metal layers may be pressed to come into contact with each other by the welding rods, and electrical current may be applied to the welding rods to weld the metal layers to each other.

A region of the printed circuit board at which the land parts are disposed may have a thickness less than that of a region of the printed circuit board at which the pattern parts are disposed.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 6 are cross-sectional views sequentially showing a conventional process of manufacturing a printed circuit board;

FIG. 7 is a cross-sectional view of a printed circuit board according to a first embodiment of the present invention;

FIG. 8 is a cross-sectional view of a printed circuit board according to a second embodiment of the present invention;

FIGS. 9 to 18 are cross-sectional views sequentially showing a process of manufacturing the printed circuit board shown in FIG. 7; and

FIGS. 19 to 25 are cross-sectional views sequentially showing a process of manufacturing the printed circuit board shown in FIG. 8.

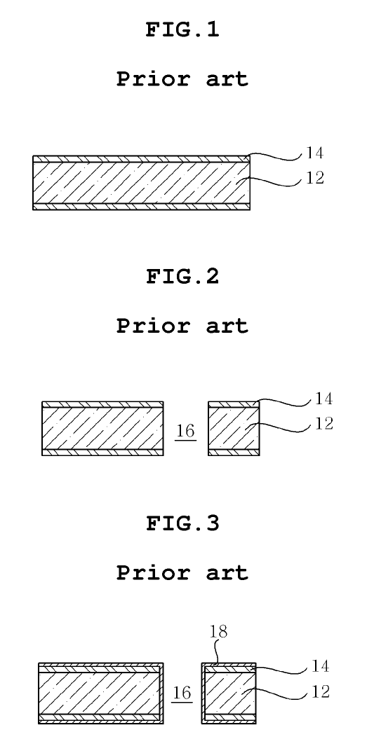

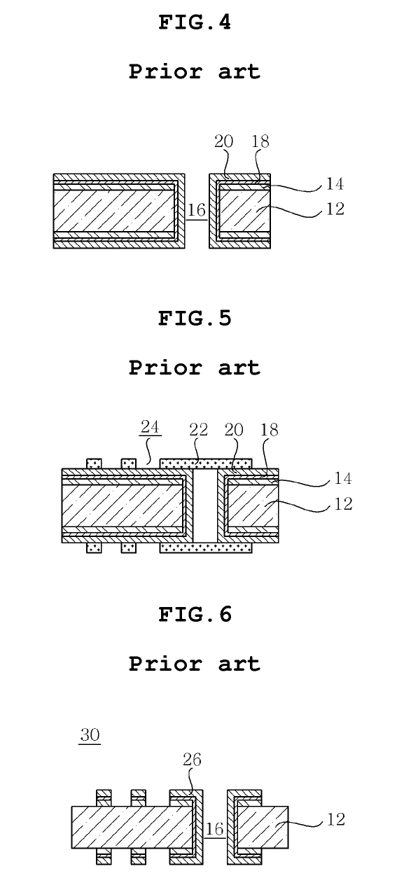

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to best describe the method he or she knows for carrying out the invention.

In the following detailed description, it should be noted that the terms “first”, “second” and the like are not intended to indicate a specified amount, sequence or significance but are intended to differentiate constituent elements. Furthermore, in designation of reference numerals, it should be noted that the same reference numerals are used throughout the different drawings to designate the same or similar components. Also, in the description of the present invention, when it is considered that the detailed description of a related art may obscure the gist of the present invention, such a detailed description may be omitted.

Hereinafter, embodiments of the present invention will be described in greater detail with reference to the following drawings.

Structure of a Printed Circuit Board

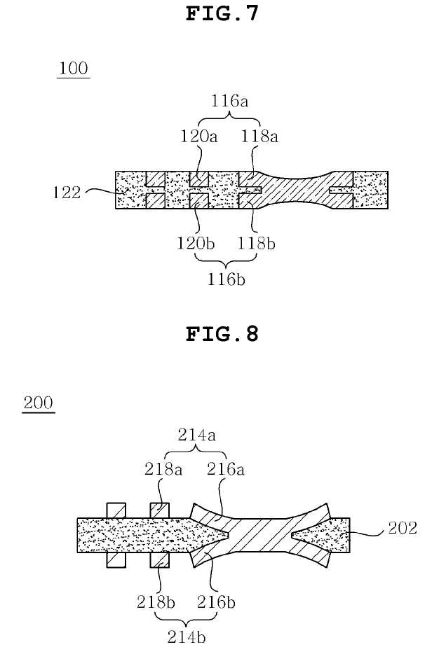

FIG. 7 is a cross-sectional view of a printed circuit board according to a first embodiment of the present invention, and FIG. 8 is a cross-sectional view of a printed circuit board according to a second embodiment of the present invention.

As will be seen from FIGS. 7 and 8, the printed circuit boards 100 and 200 according to the present invention are configured such that land parts 118a and 118b; 216a and 216b of circuit layers 116a and 116b; 214a and 214b formed on both sides of an insulating layer 122; 202 are coupled to each other to provide interlayer connection structures using electrical resistance welding, thus obviating provision of separate interlayer connection components such as vias or bumps. Hereinafter, the embodiments of the present invention, which are configured as described above, will be described in greater detail with reference to the drawings.

As shown in FIG. 7, the printed circuit board 100 according to the first embodiment of the present invention comprises the insulating layer 122, and the circuit layers 116a and 116b embedded in both sides of the insulating layer 122. The circuit layers 116a and 116b include the land parts 118a; 118b and pattern parts 120a; 120b, and the land parts 118a and 118b are coupled to each other using electrical resistance welding to provide an interlayer connection structure.

In this regard, since the land parts 118a and 118b formed on both sides of the insulating layer 122 are coupled to each other using electrical resistance welding, the land region at which the land parts 118a and 118b are coupled to each other has a thickness less than that of the pattern region at which the pattern parts 120a and 120b are formed.

As shown in FIG. 8, the printed circuit board 200 according to the second embodiment of the present invention comprises the insulating layer 202, and the circuit layers 214a and 214b formed on both sides of the insulating layer 202. The circuit layers 214a and 214b include the land parts 216a; 216b and pattern parts 218a; 218b, and the land parts 216a and 216b are coupled to each other using electrical resistance welding to provide an interlayer connection structure. The printed circuit board 200 according to the second embodiment of the present invention is substantially identical to the first embodiment except that the circuit layers 214a and 214b are not embedded in the insulating layer 202 but are formed on the insulating layer 202. Accordingly, the redundant description of the second embodiment is omitted herein.

Process of Manufacturing the Printed Circuit Board

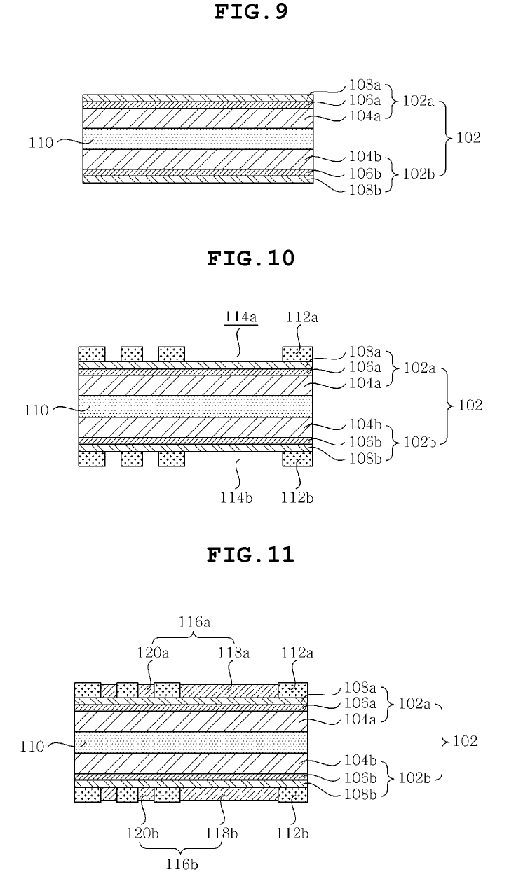

FIGS. 9 to 18 are cross-sectional views sequentially showing a process of manufacturing the printed circuit board as shown in FIG. 7. Hereinafter, the process of manufacturing the printed circuit board will be described.

As shown in FIG. 9, a carrier 102 is first prepared. In this embodiment, the carrier 102 may be embodied as a typical carrier for pattern transfer. For example, the carrier 102 may be composed of a pair of carrier members 102a and 102b and an adhesive layer 110 disposed between the pair of carrier members 102a and 102b. More specifically, the pair of carrier members 102a and 102b comprise metal base layers 104a; 104b, metal barrier layers 106a; 106b and seed layers 108a; 108b, which are sequentially layered. In this regard, the metal base layers 104a and 104b are made of metal such as copper (Cu), aluminum (Al) or iron (Fe), and the metal barrier layers 106a and 106b are made of titanium (Ti). The metal barrier layers 106a and 106b are formed on the metal base layers 104a and 104b, respectively, using a dry film-forming process such as vacuum deposition, sputtering or ion plating.

The adhesive layer 110 may be composed of a thermal adhesive which loses adhesive force after heat treatment. As the adhesive, any kind of adhesive known in the art may be used without limitation as long as the adhesive retains adhesive force while adhering to an object at an ambient temperature but loses the adhesive force after being subjected to a heat treatment thus allowing peeling off from the object. For example, the adhesive layer may be a thermal adhesive made of acrylic resin and foaming agent, which loses adhesive force after heat treatment at about 100 to 150° C., but is not limited thereto.

As shown in FIG. 10, photosensitive resists 112a and 112b are applied to the seed layers 108a and 108b of the carrier member 102, respectively, and are subjected to exposure and development processes, thus forming openings 114a and 114b through which regions for formation of circuit layers are exposed.

At this point, the openings 114a and 114b may be formed in such a way that the photosensitive resists 112a and 112b excluding the regions for formation of circuit layers are exposed to light, and the regions of the photosensitive resists 112a and 112b corresponding to a wiring pattern which are not exposed may be removed using developing solution and the like.

The photosensitive resists 112a and 112b may include a dry film and a positive liquid photo resist (P-LPR).

As shown in FIG. 11, the openings 114a and 114b are subjected to a plating process, so that circuit layers 116a and 116b including land parts 118a and 118b and pattern parts 120a and 120b are formed.

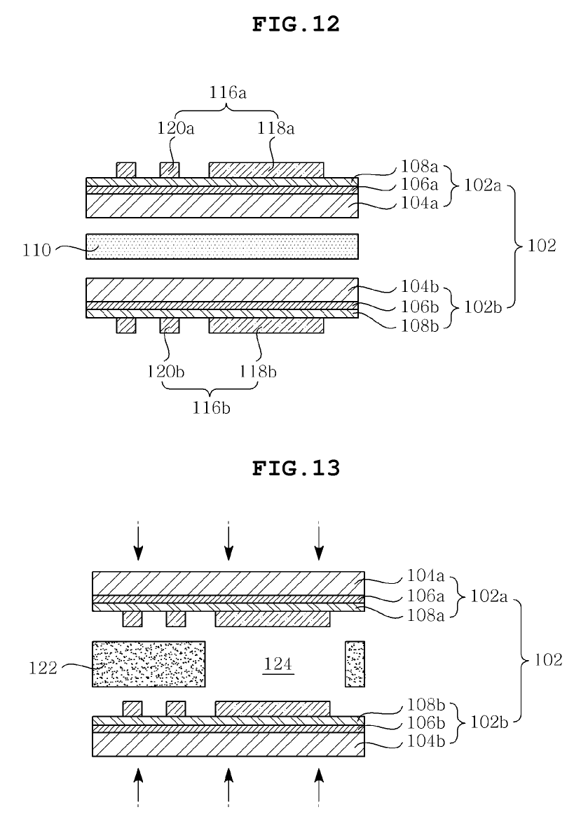

As shown in FIG. 12, the photosensitive resists 112a and 112b are peeled off, and the pair of carrier members 102a and 102b are separated from each other.

At this time, where thermal adhesive is used as the adhesive layer 110, the thermal adhesive loses the adhesive force due to heat treatment at a predetermined temperature or higher, thus allowing the separation of the pair of carrier members 102a and 102b.

As shown in FIG. 13, the pair of carrier members 102a and 102b is disposed at both sides of an insulating layer 122 having a cavity 124 corresponding to an interlayer connection region such that the circuit layers 116a and 116b are positioned in a face to face manner.

At this point, the land parts 118a and 118b of the circuit layers 116a and 116b may be positioned at both sides of the cavity 124, and the cavity 124 may have a width greater than that of the land parts 118a and 118b so as to allow the land parts 118a and 118b to be inserted into the cavity 124.

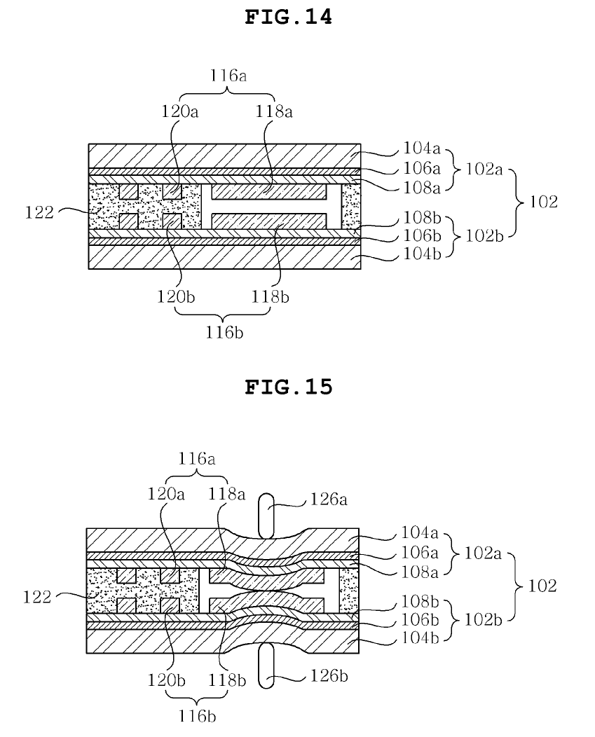

As shown in FIG. 14, the carrier members 102a and 102b are pressed toward each other so as to embed the circuit layers 116a and 116b in the insulating layer 122.

The insulating layer 122 may be in a semi-cured state so as to enable the circuit layers 116a and 116b to be embedded therein. For example, the carrier members 102a and 102b may be pressed toward each other while the insulating layer 122 is heated to or past a temperature which softens it.

At this time, the pattern parts 120a and 120b of the circuit layers 116a and 116b are embedded in the insulating layer 122, and the land parts of the circuit layers 116a and 116b are disposed to face each other while being separated from each other.

As shown in FIG. 15, welding rods 126a and 126b are placed on the land parts 118a and 118b and are pressed to bring the land parts 118a and 118b into contact with each other.

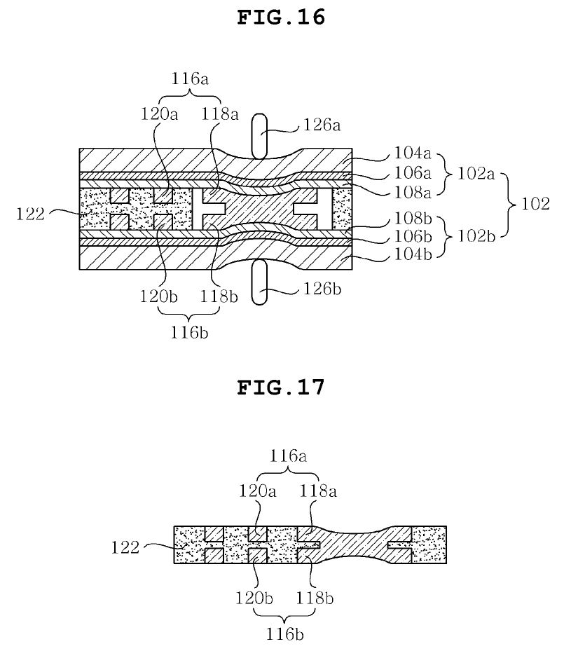

As shown in FIG. 16, electrical current is applied to the welding rods 126a and 126b while the land parts 118a and 126b are in contact with each other, so that the land parts 118a and 118b are coupled to each other through electrical resistance welding, thus allowing an interlayer connection therebetween.

As shown in FIG. 17, the insulating layer 122 is shaped at a high temperature under high pressure such that the space between the land parts 118a and 118b and the insulating layer 122 is filled with material of the insulating layer 122. Subsequently, the pair of carrier members 102 is removed. As a result, the printed circuit board 100 is obtained in which the circuit layers 116a and 116b are embedded in the insulating layer 122 and the land parts 118a and 118b are coupled to each other using the electrical resistance welding.

In this process, when the insulating layer 122 is shaped at a high temperature under high pressure, the insulating layer 122 becomes semicured or softened and thus infiltrates into the space between the land parts 118a and 118b and the insulating layer 122.

The metal base layers 104a and 104b and the metal barrier layers 106a and 106b are composed of different metal layers, and are thus removed by etching processes using different etching solutions, and the seed layers 108a and 108b are removed by a flash etching process or a quick etching process.

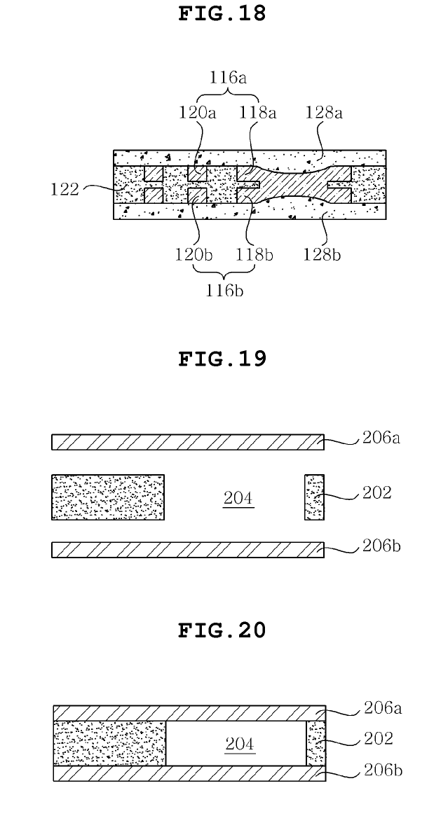

Meanwhile, solder resist layers 128a and 128b may be further provided on the insulating layer 122 in order to protect the circuit layers 116a and 116b from external environments, as shown in FIG. 18. Although FIG. 18 shows a configuration in which the solder resists 128a and 128b are formed on both sides of the insulating layer 122, an alternative configuration in which the solder resist layers 128a and 128b are not provided and buildup layers are layered on the above printed circuit board 100 may be embodied, which should be construed as falling within the scope of the present invention.

FIGS. 19 to 25 are cross-sectional views sequentially showing a process of manufacturing the printed circuit board shown in FIG. 8. Hereinafter, the process will be described with reference to the drawings.

As shown in FIG. 19, metal layers 206a and 206b are disposed at both sides of an insulating layer 202 that has a cavity 204 at an interlayer connection region.

As shown in FIG. 20, the metal layers 206a and 206b are adhered to the insulating layer 202. At this time, the insulating layer 202 may be in a semicured state such that the metal layers 206a and 206b can be adhered to the insulating layer 202.

The metal layers 206a and 206b are partially spaced apart from each other at the cavity 204 without direct contact being made therebetween.

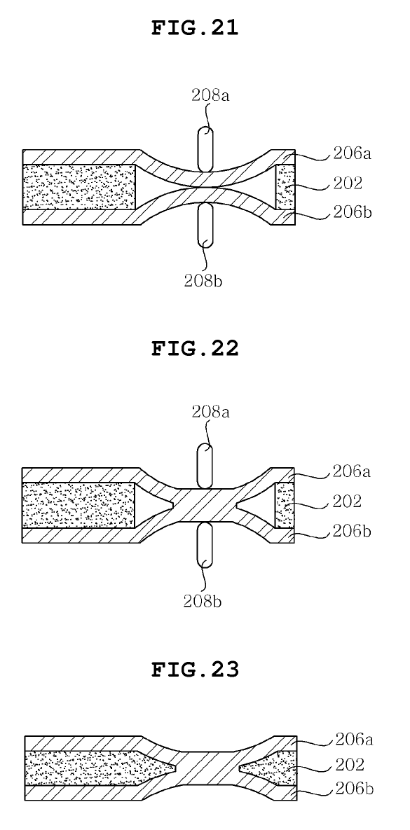

As shown in FIG. 21, welding rods 206a and 206b are placed on the metal layers 206a and 206b disposed at both sides of the cavity 204, and the metal layers 206a and 206b are pressed and are thus brought into contact with each other.

As shown in FIG. 22, while the metal layers 206a and 206b are in contact with each other, electrical current is applied to the welding rods 208a and 208b so that the metal layers 206a and 206b are partially coupled to each other using electrical resistance welding, thus allowing the interlayer connection.

As shown in FIG. 23, the insulating layer 202 is shaped at a high temperature under high pressure so that the space defined between the metal layers 206a and 206b and the insulating layer 102 is filled with the insulating layer 202.

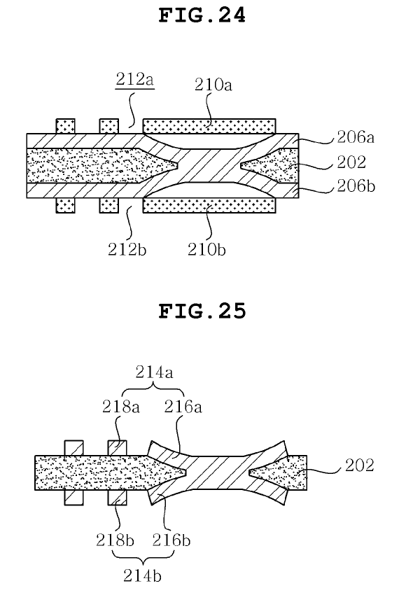

As shown in FIG. 24, photosensitive resists 210a and 210b are applied onto the metal layers 206a and 206b, respectively, and are subjected to exposure and development processes to form openings 212a and 212b through which a region for formation of a circuit layer is exposed.

At this point, the openings 212a and 212b are not formed at the regions at which the metal layers 206a and 206b are coupled to each other by the electrical resistance welding, i.e., at the regions at which land parts 216 are positioned.

As shown in FIG. 25, the regions of the metal layers 206a and 206b which are exposed through the openings 212a and 212b are removed, and then the photosensitive resists 210a and 210b are peeled off from the metal layers 206a and 206b, thus forming the circuit layers 214a and 214b including the land parts 216a and 216b and the pattern parts 218a and 218b.

By the above-described process, a printed circuit board 200, which is manufactured in a way such that the circuit layers 214a and 214b are formed on the insulating layer 202 and the land parts 216a and 216b are coupled to each other by electrical resistance welding, is provided.

As described above, since the printed circuit board according to the present invention adopts an interlayer connection structure by electrical resistance welding, it obviates the necessity for provision of separate interlayer connection structures such as vias or bumps and additional processes of forming the vias or bumps, resulting in reduction of production costs and simplification of a manufacturing process.

Furthermore, since the printed circuit board according to the present invention is configured such that circuit layers are embedded in an insulating layer, an overall height of the resulting printed circuit board is reduced, thus contributing to realization of a thin structure. In addition, the circuit layers are formed using an additive technology, and a fine circuit pattern is obtained.

Furthermore, when circuit layers are formed on an insulating layer, metal layers are etched to form circuits of the circuit layers, thus enabling realization of a fine circuit pattern.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A printed circuit board comprising:
an insulating layer; and
circuit layers disposed at both sides of the insulating layer, each of the circuit layers including a land part and a pattern part,
wherein the land parts formed on both sides of the insulating layer are coupled to each other using electrical resistance welding.

2. The printed circuit board according to claim 1, wherein the circuit layers are embedded in the insulating layer.

3. The printed circuit board according to claim 1, wherein the circuit layers are disposed on the insulating layer.

4. The printed circuit board according to claim 1, wherein a region of the printed circuit board at which the land parts are disposed has a thickness less than that of a region of the printed circuit board at which the pattern parts are disposed.

5. A method of manufacturing a printed circuit board, comprising:
(A) forming circuit layers on carrier members, respectively, each of the circuit layers including a land part and a pattern part;
(B) disposing the carrier members on both sides of an insulating layer having a cavity at an interlayer connection region such that the circuit layers of the carrier members face each other;
(C) pressing the carrier members so as to embed the circuit layers in the insulating layer;
(D) pressing the carrier members using welding rods placed thereon such that the land parts disposed at both sides of the cavity come into contact with each other, and coupling the land parts to each other by executing electrical resistance welding via the welding rods; and
(E) shaping the insulating layer at a high temperature under high pressure so as to fill a space between the circuit layers and the insulating layer with the insulating layer, and removing the carrier members.

6. The method according to claim 5, wherein the (A) disposition of the carrier members comprises:
(A1) disposing the carrier members on both sides of an adhesive layer, each of the carrier members including a metal base layer, a metal barrier layer and a seed layer;
(A2) applying photosensitive resists on the seed layers, and patterning the photosensitive resists to form openings through which regions for formation of circuit layer are exposed;
(A3) executing a plating process in the openings to form the circuit layers each including the land part and the pattern part, and removing the photosensitive resists; and
(A4) separating the carrier members disposed on both sides of the adhesive layer from each other.

7. The method according to claim 6, wherein the adhesive layer loses adhesive force when subjected to heat treatment.

8. The method according to claim 5, wherein, in the (B) disposition of the carrier members, the carrier members are disposed such that the land parts face each other with the cavity disposed therebetween.

9. The method according to claim 5, wherein, in the (B) disposition of the carrier members, the cavity of the insulating layer has a width greater than that of the land part.

10. The method according to claim 5, wherein, in the (D) pressing of the carrier members, the welding rods are placed on regions of the carrier members at which the land parts are positioned, the carrier members are pressed to bring the land parts into contact with each other by the welding rods, and electrical current is applied to the welding rods to weld the land parts to each other.

11. The method according to claim 5, wherein a region of the printed circuit board at which the land parts are disposed has a thickness less than that of a region of the printed circuit board at which the pattern parts are disposed.

12. A method of manufacturing a printed circuit board, comprising:
(A) adhering metal layers to both sides of an insulating layer having a cavity at an interlayer connection region;
(B) pressing the metal layers positioned at both sides of the cavity to bring the metal layers into contact with each other using welding rods placed on the metal layers, and coupling the metal layers to each other by electrical resistance welding;
(C) shaping the insulating layer at a high temperature under high pressure so as to fill a space between the metal layers and the insulating layer with the insulating layer; and
(D) patterning the metal layers to form circuit layers each including a land part and a pattern part.

13. The method according to claim 12, wherein, in the (B) pressing of the metal layers, the welding rods are placed on a region of the carrier members which are positioned at both sides of the cavity, the metal layers are pressed to come into contact with each other by the welding rods, and electrical current is applied to the welding rods to weld the metal layers to each other.

14. The method according to claim 12, wherein a region of the printed circuit board at which the land parts are disposed has a thickness less than that of a region of the printed circuit board at which the pattern parts are disposed.
